(19) United States
(12) Patent Application Publication
(10) Pub. No.: US 2012/0032693 A1
(43) Pub. Date: Feb. 9, 2012

(54) Crack detection in a semiconductor die and package

(75) Inventors: Jie Xue, San Ramon, CA (US); ShiJie Wen, Sunnyvale, CA (US)

(73) Assignee: CISCO TECHNOLOGY, INC., San Jose, CA (US)

(21) Appl. No.: 12/849,426

(22) Filed: Aug. 3, 2010

(51) Int. Cl. G01R 27/08; H01L 23/498

(52) U.S. Cl. 324/693; 257/738; 257/773; 257/E23.069

(57) ABSTRACT

A method is provided in which an impedance is measured between a first of a plurality of seal ring contact pads and a ground contact pad coupled to a semiconductor substrate of a semiconductor device. The first impedance value is obtained from the measured impedance, and the first impedance value is compared with a reference impedance value to determine whether a structural defect is present in the semiconductor device based on whether the first impedance value is greater than the reference impedance value.

### TECHNICAL FIELD

The present invention generally relates to a method and structure for non-destructively detecting cracks, delaminations, and other structural defects in a semiconductor device.

### BACKGROUND

Semiconductor devices are typically fabricated together on a large wafer that is then divided up, or “diced,” into multiple individual semiconductor device dies, each including an active-circuit area. The semiconductor devices are typically separated along dicing streets, and each of the diced semiconductor devices or dies may be surrounded by a seal ring. A seal ring is a semiconductor device structure that is typically formed of at least one metal and di-electrical material band around the semiconductor die. The seal ring can provide structural reinforcement and stop cracks in the semiconductor device dies that may allow undesirable moisture and mobile ionic contaminants to enter the active-circuit area of the semiconductor device die.

The process of dicing the wafer can damage areas of the semiconductor device. For example, cracks, delaminations, or other defects may form near the seal ring surrounding the dies, and these defects may propagate through the semiconductor device. Cracks, delaminations, and other defects may cause performance degradation of the semiconductor device, or in some cases, may cause the semiconductor device to fail completely. Current techniques to detect cracks and delaminations are limited. C-mode Scanning Acoustic Microscopy (C-SAM) is a common method to search for defects in semiconductor devices. However, typical C-SAM devices do not detect defects smaller than about twenty micrometers (20 μm). Moreover, C-SAM typically cannot detect, for example, small cracks in the semiconductor device die and peeling layers between packaging molding and inter-metal dielectric (IMD) layers. C-SAM techniques are often destructive and may cause damage to the packaging of the semiconductor device dies by requiring the lid removal.

Therefore, there is a need for a non-destructive method for detecting cracks, delaminations, and other structural defects in semiconductor devices that overcomes at least some of the disadvantages associated with known methods.

### BRIEF DESCRIPTION OF THE DRAWINGS

FIG. 1 is a top view of a semiconductor wafer having a plurality of active-circuit areas separated by dicing streets, each active-circuit area having a plurality of seal ring contact pads that are electrically connected to a seal ring surrounding each active-circuit area.

FIG. 2A is a cross sectional view of a semiconductor wafer showing a seal ring contact pad electrically connected to a seal ring structure and further showing a crack propagating through a substrate.

FIG. 2B is a cross sectional view of a semiconductor wafer showing a plurality of seal ring pillar structures surrounding the perimeter of a semiconductor device.

FIG. 3 is a top view of a semiconductor device including a ground contact pad and a plurality of seal ring contact pads that are electrically connected to a seal ring surrounding the active-circuit area.

FIG. 4 is a cross sectional view of a semiconductor device showing a seal ring contact pad and a ground contact pad electrically connected to a semiconductor substrate.

FIG. 5 is a schematic diagram showing an electrical circuit between the seal ring contact pad and a ground contact pad of the semiconductor device.

FIG. 6 is a cross sectional view of a packaged semiconductor device having a ball grid array electrically connected to a printed circuit board.

FIG. 7 is a flow chart depicting an example series of steps for measuring a plurality of impedance values between respective seal ring contact pads and the ground contact pad.

FIG. 8 is a flow chart depicting an example series of steps for detecting a location of a crack or delamination in a semiconductor device based on measured impedance values.

### DESCRIPTION OF EXAMPLE EMBODIMENTS

Overview

A method is provided in which an impedance is measured between a first of a plurality of seal ring contact pads and a ground contact pad coupled to a semiconductor substrate of a semiconductor device. A first impedance value is obtained from the measured impedance, and the first impedance value is compared with a reference impedance value to determine whether a structural defect is present in the semiconductor device based on whether the first impedance value is greater than the reference impedance value.

### EXAMPLE EMBODIMENTS

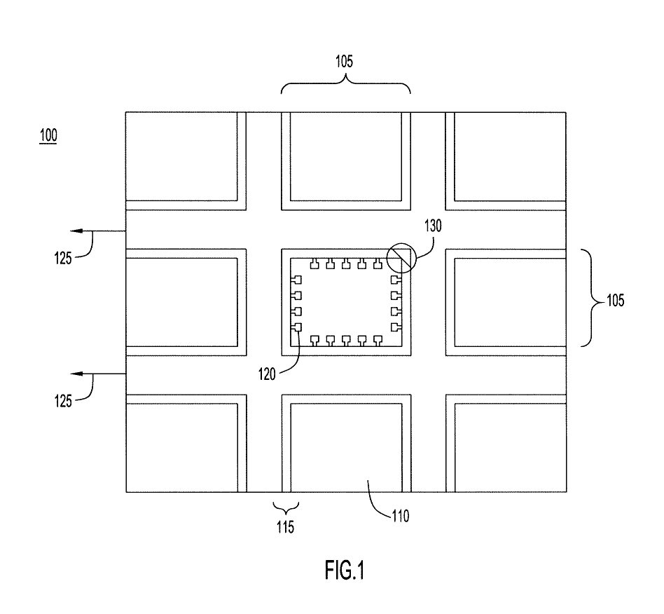

Referring first to FIG. 1, a top view of a semiconductor wafer 100 is shown. The semiconductor wafer 100 is divided into multiple semiconductor devices 105. Each of the multiple semiconductor devices 105 has an active-circuit area 110 and a seal ring 115 that surrounds the active-circuit area 110. The seal ring 115 may be any known seal ring device structure. One example of a seal ring 115 may be a structure that has a box shape extending downward through the semiconductor device and surrounding the perimeter of the semiconductor device 105. Another example of a seal ring 115 may be a plurality of pillar structures extending downward through the semiconductor device and surrounding the perimeter of the semiconductor device 105. The semiconductor devices 105 also have a plurality of seal ring contact pads 120 that are electrically connected to the seal ring 115.

Each of the semiconductor devices 105 may be separated from one another by one or more dicing streets 125. The dicing streets 125 may be scribe lines, which can serve as cutting regions during a sawing or dicing operation. In one example, the semiconductor wafer is sawed or diced along the dicing streets 125 during a sawing or dicing operation so that the semiconductor devices 105 are cut into individual semiconductor chips. The seal ring 115 surrounding each active-circuit area 110 of the semiconductor device 105 may help to slow down or stop the propagation of local cracks occurring near the semiconductor device 105. Nevertheless, despite the presence of the seal ring 115, delaminations, cracks or other structural defects can still occur and impact the semiconductor device 105 as a result of the sawing operation. For example, intrinsic thermal mechanical stress, new process material induced weak interface, or unintended wrong fabrication processes (e.g. contamination) may cause delaminations, cracks or other structural defects. Such defects often commence at a corner portion of the chip as shown by reference numeral 130 and can degrade the performance of the semiconductor device 105 when they propagate towards the active area 110 of the semiconductor device 105.

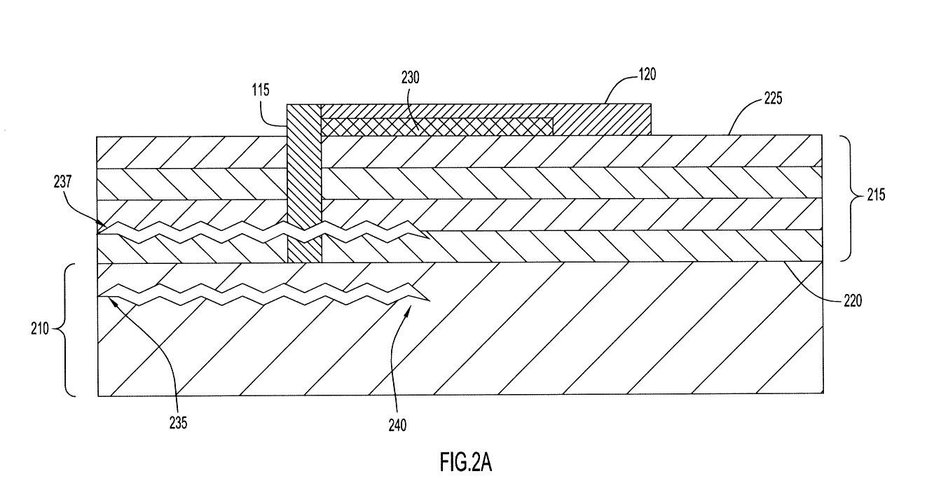

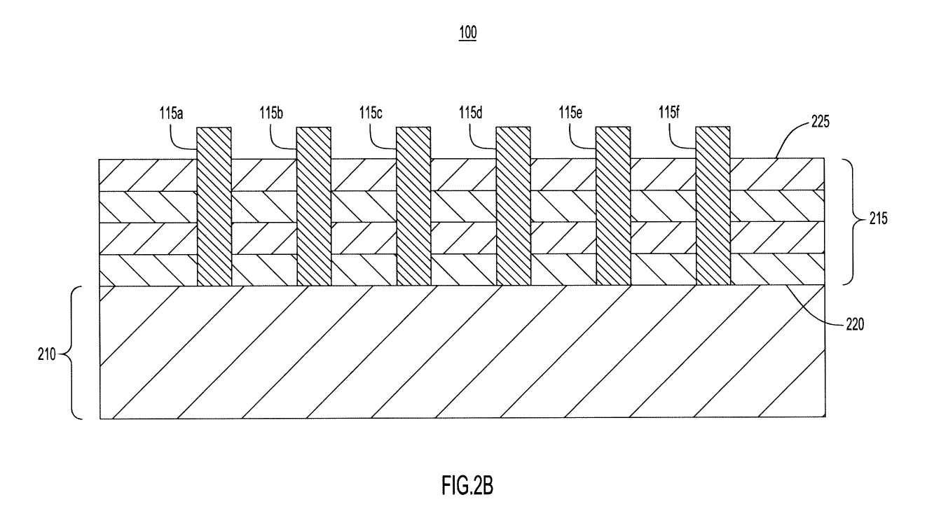

FIGS. 2A and 2B are cross sectional views of the semiconductor wafer 100. FIG. 2A shows a semiconductor wafer 100 that includes a semiconductor substrate 210 on which circuit elements such as transistors and other circuit elements are formed. The semiconductor wafer 100 also has a plurality of wiring and insulation layers 215 above the semiconductor substrate 210. The wiring and insulation layers 215 may be, for example, one or a combination of inter-layer dielectric layers, inter-metal dielectric layers, protective insulation film layers (for example, made from a silicon oxide film), wiring insulating films (for example, made from silicon nitride), or any other semiconductor and insulation suitable for this purpose. In another example, each of the wiring and insulation layers 215 may be made up of one or more low-dielectric constant (low-k) films that have dielectric constants that are several times as small as those films that are conventionally used.

FIG. 2A also shows the seal ring 115. The seal ring 115 may be fabricated from a combination of components formed through the wiring and insulation layers 215. The seal ring 115 extends substantially vertically from the top portion 220 of the semiconductor substrate 210 to a location near or above the top surface 225 of the semiconductor device 105. The seal ring 115 may be a plurality of pillar structures, shown at 115a-f in FIG. 2B, that surround the perimeter of the semiconductor device 105. The seal ring 115 is electrically coupled to a seal ring contact pad 120 that is accessible above the top surface 225 of the semiconductor device 105. FIG. 2A shows a crack that originates at a corner of the semiconductor substrate 210, as shown in reference numeral 235, and propagates through the substrate 210, as shown by reference numeral 240. FIG. 2A also shows a crack (or delamination) 237 that propagates through the wiring and insulation layers 215 and through seal ring 115. In many circumstances, cracks or delaminations propagating through the wiring and insulation layers 215 and seal ring 115 may be more prevalent than cracks that propagate through substrate 210.

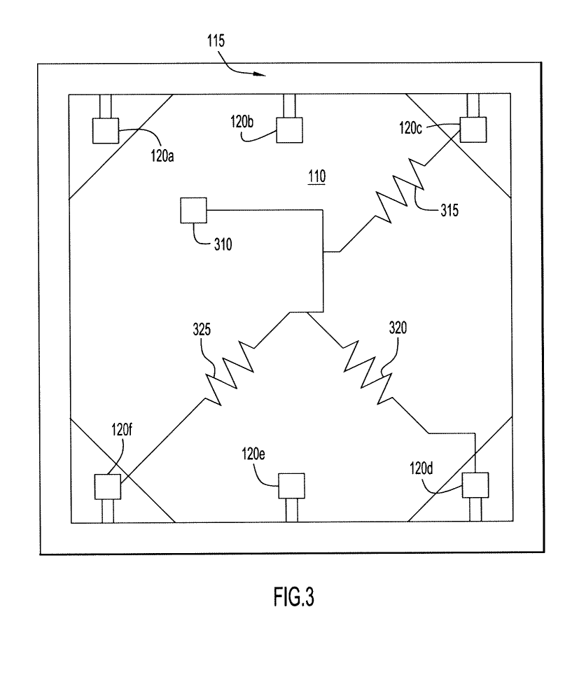

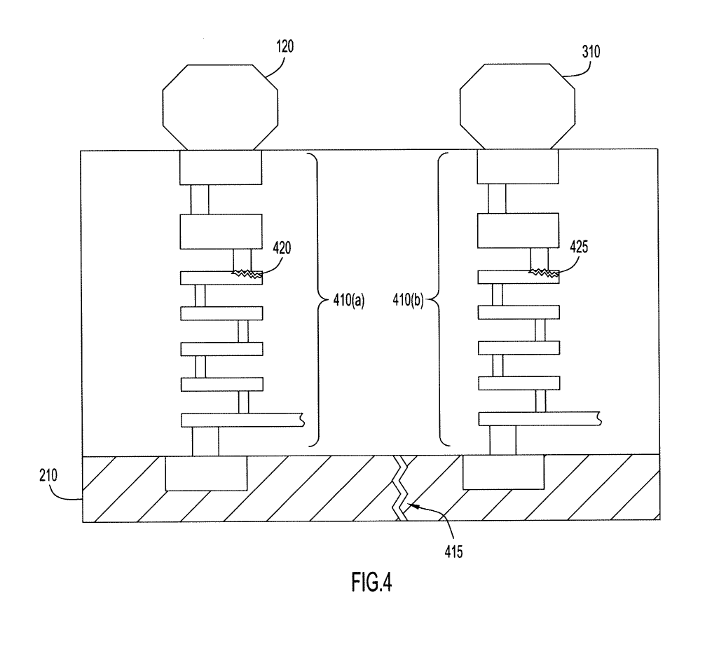

FIG. 3 shows a top view of a semiconductor device 105. The semiconductor device 105 has an active-circuit area 110 with a plurality of seal ring contact pads 120a-f that are electrically connected to the seal ring 115 that surrounds the active-circuit area 110. The seal ring contact pads 120a-f are electrically connected to the seal ring at various locations on the seal ring 115. For example, seal ring contact pads 120a, 120c, 120d, and 120f in FIG. 3 are electrically connected to a location on the seal ring 115 that is close to a corner of the active-circuit area 110, whereas seal ring contact pads 120b and 120e are electrically connected to a location on the seal ring 115 that is near a middle peripheral portion of the active-circuit area 110. FIG. 3 also shows a ground contact pad 310 that is electrically connected to the semiconductor substrate as shown in FIG. 4.

FIG. 3 further shows representations of electrical impedance between some of the seal ring contact pads and the ground contact pad 310. For example, electrical impedance 315 represents the electrical impedance between seal ring contact pad 120(c) and ground contact pad 310. Similarly, electrical impedance 320 represents the electrical impedance between seal ring contact pad 120(d) and ground contact pad 310. Electrical impedance 325 represents the electrical impedance between seal ring contact pad 120(f) and ground contact pad 310. To measure the impedance, a reference voltage or reference current may be applied between any of the plurality of seal ring contact pads and the ground contact pad 310. Further details regarding impedance measurements are provided later herein.

Reference is now made to FIG. 4. FIG. 4 is a cross sectional view of a semiconductor device 105 showing one of the seal ring contact pads 120 and a ground contact pad 310 electrically connected to semiconductor substrate 210. The seal ring contact pad 120 and ground contact pad 310 are electrically connected to the semiconductor substrate through a series of metal layers and vias 410 (note that the seal ring contact pad 120 need not be positioned directly over the seal ring 115). The metal layers and vias 410(a)-(b) provide an electrical conductive path between the semiconductor substrate 210 and the seal ring contact pad 120 and provide an electrical conductive path between the semiconductor substrate 210 and the ground contact pad 310, thus connecting the seal ring contact pad 120 with the ground contact pad 310 via the semiconductor substrate 210. As mentioned above, when, e.g., voltage is applied, an electrical impedance between the seal ring contact pad 120 and the ground contact pad 310 can be measured between the seal ring contact pad 120 and the ground contact pad 310. Accordingly, if there is a crack 415 present in the semiconductor substrate 210 or wiring layers 215, or if there is a delamination or other structural defect in the semiconductor device 105, the electrical impedance between the seal ring contact pad 120 and the ground contact pad 310 will be greater than it would be without a crack or delamination present. Additionally, a crack or delamination may be present in the series of metal layers and vias 410(a) and 410(b), as shown by reference numerals 420 and 425. The cracks or delaminations in the metal layers and vias 410(a)-(b) may cause the electrical impedance between the seal ring contact pad 120 and the ground contact pad 310 to be greater than it would be without the cracks or delaminations present. For example, crack (or delamination) 420 may increase the electrical impedance between contact pad 120 and substrate 210, thus increasing the total electrical impedance between the seal ring contact pad 120 and the ground contact pad 310. Similarly, crack (or delamination) 425 may increase the electrical impedance between ground contact pad 310 and substrate 210, thus increasing the total electrical impedance between the seal ring contact pad 120 and the ground contact pad 310.

It is noted that cracks, delaminations or other structural defects can also be detected by measuring the electrical impedance between a contact pad connected to any unused semiconductor device structure and the ground contact pad 310, where the unused semiconductor device structure is electrically coupled to the semiconductor substrate 210. For example, an unused semiconductor device structure may be any structure that is not connected to the active circuit of the semiconductor device or that is not an electrical component of the active circuit of the semiconductor device. Reference numerals 115a-f in FIG. 2B may be examples of unused semiconductor device structures. The impedance value between a contact pad connected to the unused semiconductor device structure and the ground contact pad 310 can be measured and compared to a reference impedance value to determine whether a structural defect is present in the semiconductor device.

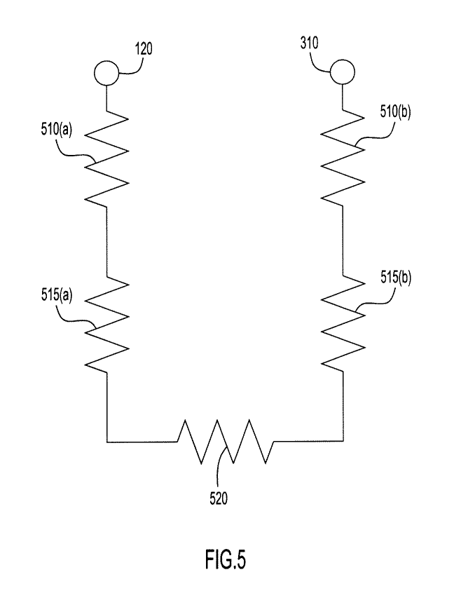

FIG. 5 shows an electrical circuit between one of the seal ring contact pads 120 and the ground contact pad 310 of the semiconductor device 105. As described above, if a reference voltage or reference current is applied between the seal ring contact pad 120 and the ground contact pad 310, the electrical impedance between the seal ring contact pad 120 and the ground contact pad 310 can be measured. FIG. 5 shows the electrical impedance between the seal ring contact pad 120 and the ground contact pad 310 as a series of electrical impedance components. Electrical impedance 510(a) represents the electrical impedance of the seal ring contact pad 120 itself, and electrical impedance 510(b) represents the electrical impedance of the ground contact pad 310 itself. Electrical impedance 515(a) represents the electrical impedance of the metal layers and vias 410(a) between the seal ring contact pad 120 and the semiconductor substrate 210. Electrical impedance 515(b) represents the electrical impedance of the metal layers and vias 410(b) between the ground contact pad 310 and the semiconductor substrate 210. Electrical impedance 520 represents the electrical impedance across the semiconductor substrate 210 that may be influenced by, for example, a crack.

As described above, a reference voltage or reference current can be applied between the seal ring contact pad 120 and the ground contact pad 310, and thus, the total electrical impedance (i.e. the sum of electrical impedance 510(a)-(b), 515(a)-(b) and 520) between the seal ring contact pad 120 and the ground contact pad 310 can be measured. For example, if a reference voltage is applied between the seal ring contact pad 120 and the ground contact pad 310, the resulting current between the seal ring contact pad 120 and the ground contact pad can be measured, and the impedance value can be calculated by dividing the reference voltage value by the measured resulting current value according to Ohm's Law. Similarly, if a reference current is applied between the seal ring contact pad 120 and the ground contact pad 310, the resulting voltage drop between the seal ring contact pad 120 and the ground contact pad 310 can be measured, and the impedance value can be calculated by dividing the measured resulting voltage between the seal ring contact pad 120 and the ground contact pad 310 by the reference current value. The impedance value between the seal ring contact pad 120 and ground contact pad 310 will be greater if there is a crack, delamination, or other structural defect in the semiconductor device 105 than if there is no crack, delamination, or other structural defect in the semiconductor device 105. Likewise, the impedance value between the seal ring contact pad 120 and the ground contact pad 310 will be greater if the seal ring contact pad 120 is electrically connected to a location near a crack, delamination, or other structural defect than if the seal ring contact pad 120 is electrically connected to a location further away from a crack, delamination, or other structural defect. Any one of the impedances 510(a)-(b) and 515(a)-(b) can contribute to a change in impedance value between the seal ring contact pad 120 and the ground contact pad 310, thus indicating that a defect is present somewhere within the semiconductor device.

Since the plurality of seal ring contact pads 120 are electrically connected to the seal ring 115 at various locations around the active-circuit 110, a reference voltage or reference current can be applied between each of the plurality seal ring contact pads 120 and the ground contact pad 310 to measure respective impedance values between the seal ring contact pads 120 and the ground contact pad 310 at various locations along the seal ring 115 surrounding the active-circuit 110. As a result, the location of any cracks, delaminations, or structural defects can be determined by comparing the measured impedance values with one another.

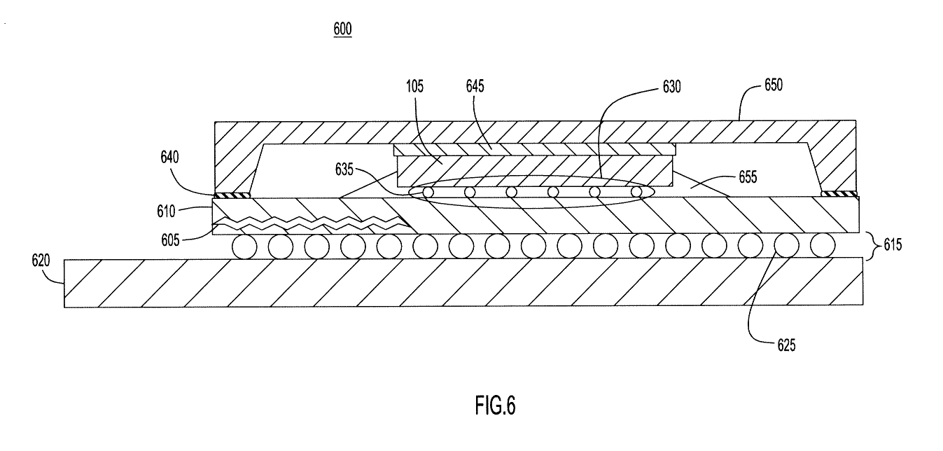

Reference is now made to FIG. 6. FIG. 6 is a cross sectional view of a packaged semiconductor device 105. The package 600 has a ball grid array (BGA) 615 that is electrically connected to a printed circuit board (PCB) 620, and the ball grid array 615 is comprised of a plurality of solder BGA balls 625. The BGA balls 625 are disposed on a bottom surface of a package substrate 610 of the package 600 and may be used to conduct electrical signals from the PCB 620 to the semiconductor device 105 through the package substrate 610.

Package 600 also has a solder bump array 630 that is comprised of a plurality of solder bumps 635, some of which may be connected to respective seal ring contact pads 120 and the ground contact pad 310 of the semiconductor device 105. The solder bumps 635 may also be electrically connected to one or more of the BGA balls 625 through the package substrate 610 to allow electrical signals to be conducted from the PCB 620 to the semiconductor device 105 through the package substrate 610. Package 600 also comprises conventional components including a lip seal adhesive 640, thermal interface material 645, heat spreader 650, and under fill 655.

At least some of the BGA balls (e.g. often located in the corner or center of the package 600) that are not electrically connected to active-circuit elements of the semiconductor device 105 may instead be electrically connected to solder bumps 635 that are connected to seal ring contact pads. These BGA balls 625 can then be used to measure the electrical impedance between each of the seal ring contact pads 120 and the ground contact pad 310. For example, the BGA balls 625 can be electrically coupled to the PCB 620, and a reference voltage or reference current can be applied from the PCB 620 to the BGA balls 625 that are electrically connected to the appropriate solder bumps 635 of the seal ring contact pads 120 and the ground contact pad 310. The electrical impedance between each of the seal ring contact pads 120 and the ground contact pad 310 can then be measured according to the techniques described above.

Cracks, delaminations and other structural defects may also occur in package 600. For example, a crack (shown at reference numeral 605) may occur and propagate through the package substrate 610. The crack can be detected by measuring an impedance between a first of the plurality of non-active-circuit connect balls of the ball grid array 615 and a second of the plurality of non-active-circuit connect balls of the ball grid array 615. The impedance value between the non-active-circuit connect balls can then be compared to a reference impedance value to determine whether a structural defect is present in package 600.

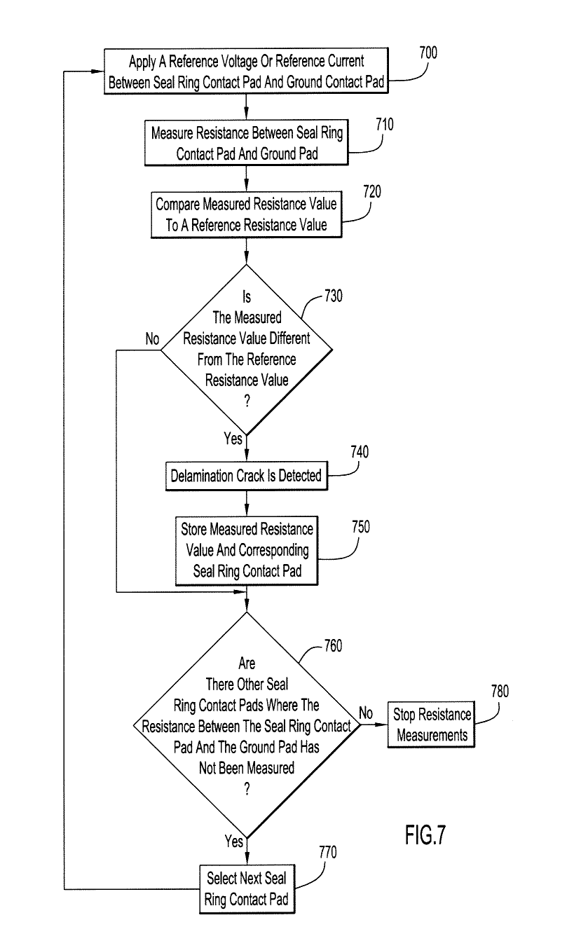

FIG. 7 is a flow chart depicting an example series of steps for measuring a plurality of impedance values between the seal ring contact pads 120 and the ground contact pad 310. At step 700, a reference voltage or reference current is applied between one of the plurality of seal ring contact pads 120 and the ground contact pad 310. At step 710, an impedance is measured between the seal ring contact pad 120 and ground contact pad 310, using the techniques described above. For example, if a reference voltage is applied between the seal ring contact pad 120 and the ground contact pad 310, the impedance can be determined by measuring a resulting current value between the seal ring contact pad 120 and the ground contact pad 310 and by dividing the reference voltage value by the resulting current value according to Ohm's Law. Similarly, if a reference current is applied between the seal ring contact pad 120 and the ground contact pad 310, the impedance can be determined by measuring a resulting voltage drop between the seal ring contact pad 120 and the ground contact pad 310 and dividing the measured resulting voltage value by the reference current value.

At step 720, the impedance value measured in step 710 is compared to a reference impedance value. The reference impedance value may be a predetermined reference value that corresponds to the impedance value between the seal ring contact pad 120 and the ground contact pad 310 of a semiconductor device 105 known not to be defective. The reference impedance value may also represent a range of impedance values.

At step 730, a determination is made as to whether the impedance value measured in step 710 is different from the reference impedance value. If the impedance value measured in step 710 is different from the reference impedance value, or if the measured impedance value is outside of a range of reference impedance values, a determination is made at step 740 that a delamination or crack is likely present in the semiconductor device 105, and the impedance value measured in step 710, as well as the corresponding seal ring contact pad where the impedance value was measured, is stored at step 750.

Step 760 is performed both if the impedance value measured in step 710 is the same as the reference impedance value or is within a range of reference impedance values and also after step 750. At this step, a determination is made as to whether there are other seal ring contact pads 120 for which the impedance has not been measured. If there are other seal ring contact pads 120 for which the impedance has not been measured, the next seal ring contact pad is selected at step 770, and the series of steps, starting at step 700, is repeated for the selected seal ring contact pad. If impedance measurements have been made at all of the seal ring contact pads 120, then the impedance measurements end at step 780. Semiconductor devices 105 having impedances greater than a threshold level (which would be at least as great as the reference impedance) may be discarded as defective.

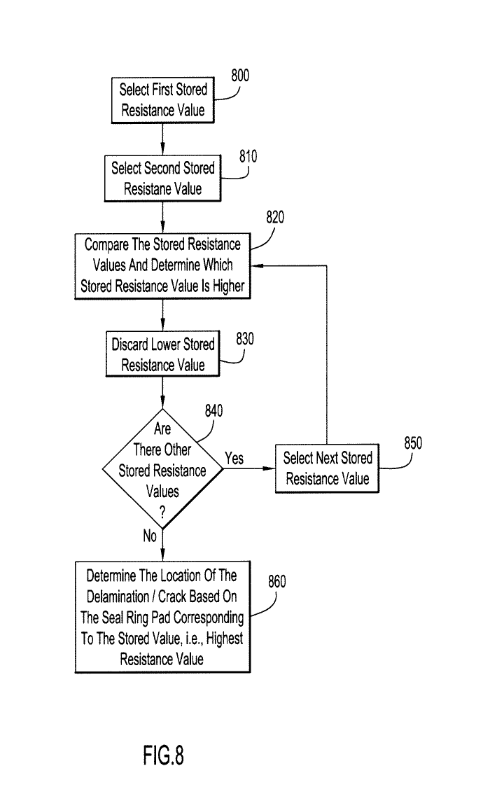

FIG. 8 is a flow chart depicting an example series of steps for detecting a location of a crack or delamination in a semiconductor device 105 based on measured impedance values. At step 800, a first stored impedance value is selected from the group of impedance values stored in step 750 described in FIG. 7. At step 810, a second stored impedance value is selected from the group of stored impedance values. At step 820, the selected stored impedance values are compared to one another to determine which stored impedance value is higher. At step 830 the lower stored impedance value is discarded from the group of stored impedance values, and a determination is made at step 840 as to whether there are any remaining stored impedance values in the group. If there are other stored impedance values, a next stored impedance value is selected at step 850, and steps 820, 830 and 840 are repeated. If there are no other stored impedance values, the location of the delamination or crack is determined at step 860 by first identifying the seal ring contact pad 120 that corresponds to the highest impedance value and then determining the location on the seal ring 115 that corresponds to the seal ring contact pad 120 identified with the highest impedance value. This methodology makes it possible to better pinpoint where defects are occurring so that changes or adjustments to the manufacturing process and desired structures (e.g., dicing) may be made.

In sum, a method is provided in which an impedance is measured between a first of a plurality of seal ring contact pads and a ground contact pad coupled to a semiconductor substrate of a semiconductor device. The first impedance value is obtained from the measured impedance, and the first impedance value is compared with a reference impedance value to determine whether a structural defect is present in the semiconductor device based on whether the first impedance value is greater than the reference impedance value.

Similarly, a semiconductor device is provided that comprises an active-circuit region and a seal ring surrounding the active-circuit region extending between a substrate of the semiconductor device and a top portion of the semiconductor device. The semiconductor device also has a plurality of seal ring contact pads that are electrically coupled to the seal ring, and a ground contact pad that is electrically connected to the semiconductor substrate.

The above description is intended by way of example only.

What is claimed is:

1. A method comprising:
measuring an impedance between a first of a plurality of seal ring contact pads and a ground contact pad coupled to a semiconductor substrate of a semiconductor device to obtain a first impedance value, the plurality of seal ring contact pads being electrically connected to a seal ring that surrounds an active-circuit area of the semiconductor device;
comparing the first impedance value with a reference impedance value; and
determining whether a structural defect is present in the semiconductor device based on whether the first impedance value is greater than the reference impedance value.

2. The method of claim 1, wherein measuring comprises measuring the impedance between the first of the plurality of seal ring contact pads and the ground contact pad by applying a reference voltage between the first of the plurality of seal ring contact pads and the ground contact pad and by measuring a resulting current between the first of the plurality of seal ring contact pads and the ground contact pad.

3. The method of claim 1, wherein measuring comprises measuring the impedance between the first of the plurality of seal ring contact pads and the ground contact pad by applying a reference current between the first of the plurality of seal ring contact pads and the ground contact pad and by measuring a resulting voltage drop between the first of the plurality of seal ring contact pads and the ground contact pad.

4. The method of claim 1, further comprising:
measuring an impedance between a second seal ring contact pad of the plurality of seal ring contact pads and the ground contact pad to obtain a second impedance value;
comparing the first and second impedance values to each other; and
identifying a location of the structural defect based on a difference between the first and second impedance values.

5. The method of claim 4, wherein identifying comprises identifying the location of the structural defect based on a location of the seal ring contact pad having a highest impedance value.

6. The method of claim 4, wherein measuring the impedance between the second seal ring contact pad of the plurality of seal ring contact pads and the ground contact pad comprises measuring the impedance between the second seal ring contact pad and the ground contact pad through at least one of a plurality of non-active-circuit connect balls of a ball grid array of a semiconductor package.

7. The method of claim 4, wherein measuring the impedance between the second seal ring contact pad of the plurality of seal ring contact pads and the ground contact pad comprises measuring the impedance between the second seal ring contact pad and the ground contact pad via a printed circuit board connected to a plurality of non-active-circuit connect balls of a ball grid array.

8. A semiconductor device, comprising:
an active-circuit region;
a seal ring surrounding the active-circuit region, the seal ring extending between a substrate of the semiconductor device and a top portion of the semiconductor device;
a plurality of seal ring contact pads electrically coupled to the seal ring; and
a ground contact pad electrically connected to the semiconductor substrate.

9. The device of claim 8, wherein the seal ring is comprised of a plurality of metallization layers and vias.

10. The device of claim 8, wherein at least some of the plurality of seal ring contact pads are electrically connected to a portion of the seal ring that is near a corner of the active-circuit region.

11. The device of claim 8, wherein the seal ring comprises a plurality of pillars surrounding the active-circuit region.

12. The device of claim 8, wherein the semiconductor device is one of a plurality of similar semiconductor devices on a single wafer.

13. The device of claim 8, wherein the seal ring contact pads are electrically connected respectively to a plurality of non-active-circuit connect balls of a ball grid array disposed on a bottom surface of a package substrate of a semiconductor package comprising the semiconductor device.

14. The device of claim 13, wherein at least one of the non-active-circuit connect balls of the ball grid array is located near a corner of the semiconductor package.

15. The device of claim 13, wherein the ground contact pad is electrically connected to a second ball of the plurality non-active-circuit connect balls of a ball grid array disposed on the bottom surface of the package substrate.

16. A method comprising:
measuring an impedance between a first semiconductor device contact pad electrically connected to a first unused semiconductor device structure coupled to a semiconductor substrate of a semiconductor device and a ground contact pad coupled to the semiconductor substrate of the semiconductor device to obtain a first impedance value;
comparing the first impedance value with a reference impedance value; and
determining whether a structural defect is present in the semiconductor device based on whether the first impedance value is greater than the reference impedance value.

17. The method of claim 16, further comprising:
measuring an impedance between a second semiconductor device contact pad electrically connected to a second unused semiconductor device structure and the ground contact pad to obtain a second impedance value;
comparing the first and second impedance values to each other; and
identifying a location of the structural defect based on a difference between the first and second impedance values.

18. A method comprising:
measuring an impedance between a first non-active-circuit connect ball in a ball grid array disposed on a bottom surface of a package substrate of a semiconductor device package and a second ball in the ball grid array to obtain a first impedance value;
comparing the first impedance value with a reference impedance value; and
determining whether a structural defect is present in the semiconductor device package based on whether the first impedance value is greater than the reference impedance value.

19. The method of claim 18, wherein measuring comprises measuring the impedance between the first ball in the ball grid array and the second ball in the ball grid array, wherein the first and second balls are connected to first and second semiconductor device structures that extend from a top surface of a semiconductor device to a semiconductor substrate.

20. The method of claim 18, further comprising:
measuring an impedance between the second ball in the ball grid array and a third ball in the ball grid array to obtain a second impedance value;
comparing the first and second impedance values to each other; and
identifying a location of the structural defect based on a difference between the first and second impedance values.
